(19) United States
(12) Patent Application Publication
(10) Pub. No.: US 2025/0125204 A1
(43) Pub. Date: Apr. 17, 2025

(54) SEMICONDUCTOR DEVICE

(71) Applicant: Mitsubishi Electric Corporation, Tokyo (JP)

(72) Inventor: Yu FUKUNAGA, Tokyo (JP)

(73) Assignee: Mitsubishi Electric Corporation, Tokyo (JP)

(21) Appl. No.: 18/766,870

(22) Filed: Jul. 9, 2024

(30) Foreign Application Priority Data
Oct. 11, 2023 (JP) 2023-175727

(51) Int. Cl. H01L 23/24; H01L 23/04

(52) U.S. Cl. CPC H01L 23/24; H01L 23/04

(57) ABSTRACT

A semiconductor device includes: a container having a metal base plate and a case, an insulating substrate disposed on the metal base plate in the container; a semiconductor element mounted on the insulating substrate; and a silicone gel filled in the container and sealing the insulating substrate and the semiconductor element. The groove having a predetermined dimension capable of generating a capillary phenomenon is provided in a portion located above the upper surface of the silicone gel on the inner peripheral surface of the case.

### BACKGROUND OF THE INVENTION

### Field of the Invention

The present disclosure relates to a semiconductor device.

### Description of the Background Art

In a sealing step in a manufacturing process of a semiconductor device, a part of a silicone gel creeps up in a container due to volume expansion of the silicone gel generated at the time of defoaming and heating of the silicone gel filled in the container. In addition, a protrusion failure of the silicone gel sometimes occurs, in which the silicone gel that has crept up at the time of covering the container is pushed out to the upper portion of the container.

For example, Japanese Patent Application Laid-Open No. 2019-110217 describes a technique of forming a bent portion in which an external lead-out terminal protruding from an upper surface of a resin sealant (corresponding to a silicone gel) is bent, intentionally guiding the resin sealant by surface tension to creep up, and then depositing the resin sealant on the bent portion of the external lead-out terminal, thereby suppressing protrusion of the resin sealant.

However, in the technique described in Japanese Patent Application Laid-Open No. 2019-110217, since the effect of suppressing protrusion of the silicone gel largely depends on the position and shape of the external lead-out terminal, it has been difficult to adopt this technique depending on the type of semiconductor device. Even if it can be adopted, it is necessary to consider interference with other components such as a wire, and thus the ease of manufacturing is lacking.

### SUMMARY

An object of the present disclosure is to provide a technique capable of enhancing ease of manufacturing a semiconductor device and suppressing protrusion of a silicone gel filled in a container.

The semiconductor device according to the present disclosure includes a container, an insulating substrate, a semiconductor element, and a silicone gel. The container includes a bottom portion and a side wall portion. The insulating substrate was disposed on the bottom portion of the container. The semiconductor element was mounted on the insulating substrate. The silicone gel is filled in the container to seal the insulating substrate and the semiconductor element. A groove having a predetermined dimension capable of generating a capillary phenomenon is provided in a portion located above an upper surface of the silicone gel in an inner peripheral surface of the side wall portion.

Since the silicone gel that has crept up in the container enters the groove due to a capillary phenomenon, it is possible to suppress protrusion of the silicone gel filled in the container. In addition, when this structure is adopted, it is not necessary to consider interference with other components in the container, and thus, it is possible to enhance the ease of manufacturing the semiconductor device.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first preferred embodiment;

FIG. 2 is a top view of the semiconductor device according to the first preferred embodiment;

FIG. 3 is a sectional view of a semiconductor device according to a second preferred embodiment;

FIG. 4 is a cross-sectional view of a semiconductor device according to a third preferred embodiment; and

FIG. 5 is a cross-sectional view of a semiconductor device according to a fourth preferred embodiment.

### DESCRIPTION OF THE PREFERRED EMBODIMENTS

### First Preferred Embodiment

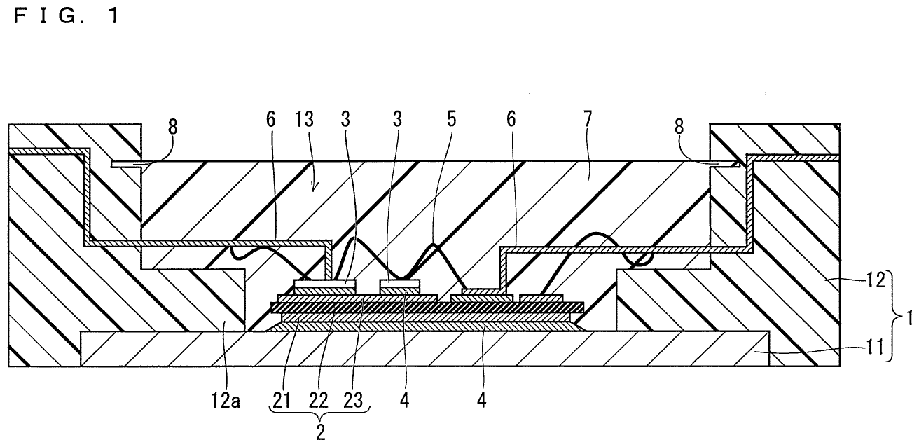

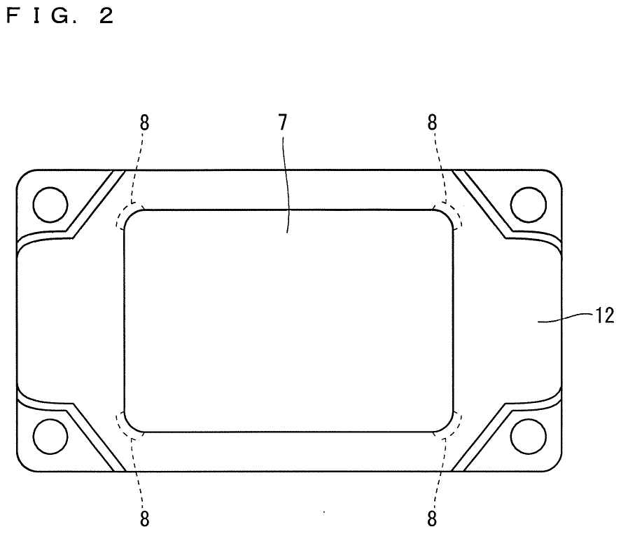

A first preferred embodiment will be described below with reference to the drawings. FIG. 1 is a cross-sectional view of a semiconductor device according to the first preferred embodiment. FIG. 2 is a top view of the semiconductor device according to the first preferred embodiment.

As illustrated in FIG. 1, the semiconductor device includes a container 1, an insulating substrate 2, a semiconductor element 3, a wire 5, a terminal 6, and a silicone gel 7.

The container 1 includes a metal base plate 11 as a bottom portion and a case 12 as a side wall portion. The case 12 is formed in a rectangular frame shape in top view, and is attached to a peripheral edge portion of the metal base plate 11. A lower end portion of the inner peripheral portion of the case 12 is provided with a protruding portion 12a protruding toward the inner peripheral side over the entire circumference, and a lower surface of the protruding portion 12a is attached to an upper surface of a peripheral edge portion of the metal base plate 11. On the inner peripheral side of the case 12, an opening 13 that is open upward and has a rectangular shape in top view is formed.

The insulating substrate 2 includes an insulating layer 22, a metal pattern 21 provided on a lower surface of the insulating layer 22, and a metal pattern 23 provided on an upper surface of the insulating layer 22, and is bonded onto a metal base plate 11 in the container 1 by a bonding material 4. The bonding material 4 is solder or the like.

The semiconductor element 3 is mounted on the insulating substrate 2 via the bonding material 4. The semiconductor element 3 is, for example, an insulated gate bipolar transistor (IGBT), a reverse conducting-IGBT (RC-IGBT), a metal oxide semiconductor field effect transistor (MOSFET), or a free wheeling diode (FWD). A material of the semiconductor element 3 may be normal silicon (Si), or may be a wide band gap semiconductor such as silicon carbide (SiC), gallium nitride (GaN), or diamond. When the material of the semiconductor element 3 is a wide band gap semiconductor, stable operation under high temperature and high voltage, and high switching speed can be achieved. Note that the number of semiconductor elements 3 may be one or more.

One end side of the terminal 6 is attached to the case 12, and the other end portion of the terminal 6 is bonded to the metal pattern 23 of the insulating substrate 2. The wire 5 connects the terminal 6 and the metal pattern 23 of the insulating substrate 2, and connects the semiconductor elements 3 to each other. The wire 5 connects the semiconductor element 3 and the terminal 6.

The silicone gel 7 is filled in the case 12 of the container 1 to seal the insulating substrate 2 and the semiconductor element 3.

Next, features of the first preferred embodiment will be described. As shown in FIG. 1, a groove 8 having a predetermined dimension capable of generating a capillary phenomenon is provided in a portion located above the upper surface of the silicone gel 7 on the inner peripheral surface of the case 12. A part of the silicone gel 7 creeps up in the case 12 due to volume expansion of the silicone gel 7 generated at the time of defoaming and heating of the silicone gel 7 filled in the case 12. However, as described above, since the groove 8 is provided in the portion located above the upper surface of the silicone gel 7, it is not necessary to consider interference with other components in the container 1, and the silicone gel 7 that has crept up in the case 12 can enter the groove 8 by the capillary phenomenon.

Here, since the height position of the silicone gel 7 that creeps up in the case 12 is empirically 1 mm or more and 2 mm or less, the groove 8 may be provided in a portion located about several mm above the upper surface of the silicone gel 7 in the inner peripheral surface of the case 12.

In addition, the groove 8 needs to have a length in the height direction of 0.8 mm or more and 1.2 mm or less in order to generate the capillary phenomenon. As illustrated in FIG. 2, it is desirable that four grooves 8 are provided, and the four grooves 8 are provided at four corners of the case 12. This is because the four corners of the case 12 have the largest surface tension with the silicone gel 7, and there is a high possibility of affecting the creeping up of the silicone gel 7. In addition, in order for the groove 8 to more effectively generate the capillary phenomenon, the dimension of the groove 8 desirably has a length in the height direction of 0.8 mm or more and 1.2 mm or less, a length in the lateral direction of 0.8 mm or more and 1.2 mm or less, and a depth of 1.6 mm or more and 2.4 mm or less.

As described above, the semiconductor device according to the first preferred embodiment includes: the container 1 having the metal base plate 11 and the case 12; the insulating substrate 2 disposed on the metal base plate 11 in the container 1; the semiconductor element 3 mounted on the insulating substrate 2; and the silicone gel 7 filled in the container 1 and sealing the insulating substrate 2 and the semiconductor element 3. The groove 8 having a predetermined dimension capable of generating a capillary phenomenon is provided in a portion located above the upper surface of the silicone gel 7 on the inner peripheral surface of the case 12. Specifically, the groove 8 has a length in the height direction of 0.8 mm or more and 1.2 mm or less.

Therefore, since the silicone gel 7 that has crept up in the case 12 of the container 1 enters the groove 8 due to the capillary phenomenon, it is possible to suppress the protrusion of the silicone gel 7 filled in the container 1. In addition, when this structure is adopted, it is not necessary to consider interference with other components in the container 1, and thus, it is possible to enhance the ease of manufacturing the semiconductor device.

In addition, the semiconductor device includes the four grooves 8, the case 12 is formed in a rectangular frame shape in top view, and the four grooves 8 are provided at four corners of the case 12 and have a length in the height direction of 0.8 mm or more and 1.2 mm or less, a length in the lateral direction of 0.8 mm or more and 1.2 mm or less, and a depth of 1.6 mm or more and 2.4 mm or less.

Therefore, since the capillary phenomenon can be more effectively generated with respect to the groove 8, the effect of suppressing the protrusion of the silicone gel 7 filled in the container 1 is improved.

### Second Preferred Embodiment

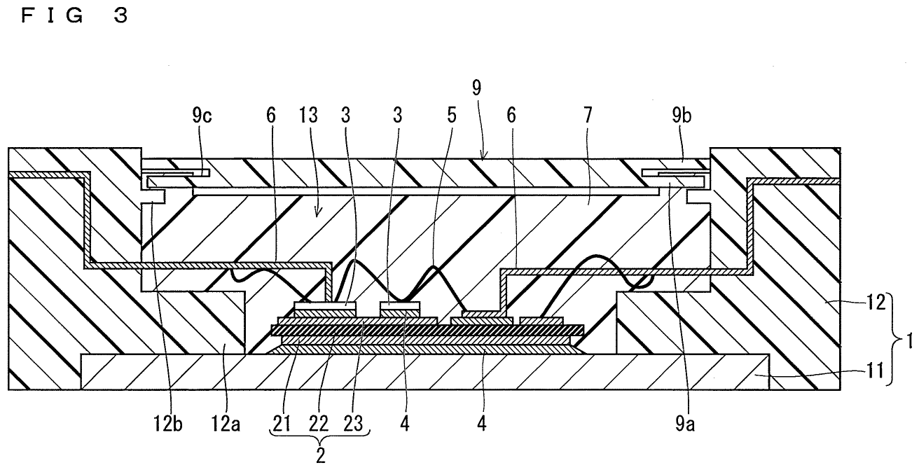

Next, a semiconductor device according to a second preferred embodiment will be described. FIG. 3 is a cross-sectional view of the semiconductor device according to the second preferred embodiment. Note that, in the second preferred embodiment, the same components as those described in the first preferred embodiment are denoted by the same reference numerals, and description thereof is omitted.

As illustrated in FIG. 3, in the second preferred embodiment, the semiconductor device includes a lid 9 provided with a groove 9c instead of the groove 8 of the first preferred embodiment. The lid 9 is attached to an attachment portion 12b protruding from the inner peripheral surface of the case 12 toward the inner peripheral side with a gap so as to cover the opening 13. The gap between the lid 9 and the attachment portion 12b has a size through which the silicone gel 7 can pass. The attachment portion 12b may be continuously provided over the entire circumference of the inner peripheral surface of the case 12, or a plurality of attachment portions 12b may be intermittently provided over the entire circumference of the inner peripheral surface of the case 12.

The lid 9 is formed in a rectangular shape in top view, and includes an inner lid 9a and an outer lid 9b. The inner lid 9a constitutes a lower portion of the lid 9 and faces the silicone gel 7. The outer lid 9b constitutes an upper portion of the lid 9, and is located above the inner lid 9a. The inner lid 9a is formed to be smaller than the outer lid 9b, and the top view contour of the inner lid 9a is located on the inner peripheral side of the top view contour of the outer lid 9b. Specifically, the top view contour of the inner lid 9a is located on the inner peripheral side of the top view contour of the outer lid 9b by 0.8 mm or more and 1.2 mm or less. As a result, a gap through which the silicone gel 7 can pass is formed between the inner peripheral surface of the case 12 and the inner lid 9a.

The groove 9c recessed toward the inner peripheral side is provided between the peripheral edge portion of the outer lid 9b and the peripheral edge portion of the inner lid 9a, and a gap between the inner peripheral surface of the case 12 and the inner lid 9a and the groove 9c communicate with each other. The groove 9c is provided over the entire circumference between the peripheral edge portion of the outer lid 9b and the peripheral edge portion of the inner lid 9a, and has a depth of 0.8 mm or more and 1.2 mm or less and a length in the height direction corresponding to 24% or more and 36% or less of the thickness of the lid 9.

A part of the silicone gel 7 creeps up in the case 12 due to volume expansion of the silicone gel 7 generated at the time of defoaming and heating of the silicone gel 7 filled in the case 12. The silicone gel 7 that has crept up in the case 12 is pressed at the time of covering the container 1, and a protrusion failure of the silicone gel 7 sometimes occurs. However, as described above, since the groove 9c is provided between the peripheral edge portion of the outer lid 9b and the peripheral edge portion of the inner lid 9a, it is not necessary to consider interference with other components in the container 1, and the silicone gel 7 compressed at the time of covering enters the groove 9c via the gap between the lid 9 and the attachment portion 12b and the gap between the inner peripheral surface of the case 12 and the inner lid 9a, so that the silicone gel 7 can be kept in the groove 9c.

As described above, the semiconductor device according to the second preferred embodiment includes: the container 1 having the metal base plate 11, the case 12, and the opening 13 opening upward; the insulating substrate 2 disposed on the metal base plate 11 in the container 1; the semiconductor element 3 mounted on the insulating substrate 2; the silicone gel 7 filled in the container 1 and sealing the insulating substrate 2 and the semiconductor element 3; and the lid 9 covering the opening 13 of the container 1. The lid 9 includes the inner lid 9a facing the silicone gel 7 and the outer lid 9b located above the inner lid 9a, the top view contour of the inner lid 9a is located on the inner peripheral side of the top view contour of the outer lid 9b, and the groove 9c recessed to the inner peripheral side is provided between the peripheral edge portion of the outer lid 9b and the peripheral edge portion of the inner lid 9a.

Specifically, the top view contour of the inner lid 9a is located on the inner peripheral side by 0.8 mm or more and 1.2 mm or less from the top view contour of the outer lid 9b, and the groove 9c is provided over the entire circumference between the peripheral edge portion of the outer lid 9b and the peripheral edge portion of the inner lid 9a, and has a depth of 0.8 mm or more and 1.2 mm or less and a length in the height direction corresponding to 24% or more and 36% or less of the thickness of the lid 9.

Therefore, since the silicone gel 7 that has crept up in the container 1 is compressed at the time of covering the container 1 and enters the groove 9c, it is possible to suppress protrusion of the silicone gel 7 filled in the container 1. In addition, when this structure is adopted, it is not necessary to consider interference with other components in the container 1, and thus, it is possible to enhance the ease of manufacturing the semiconductor device.

### Third Preferred Embodiment

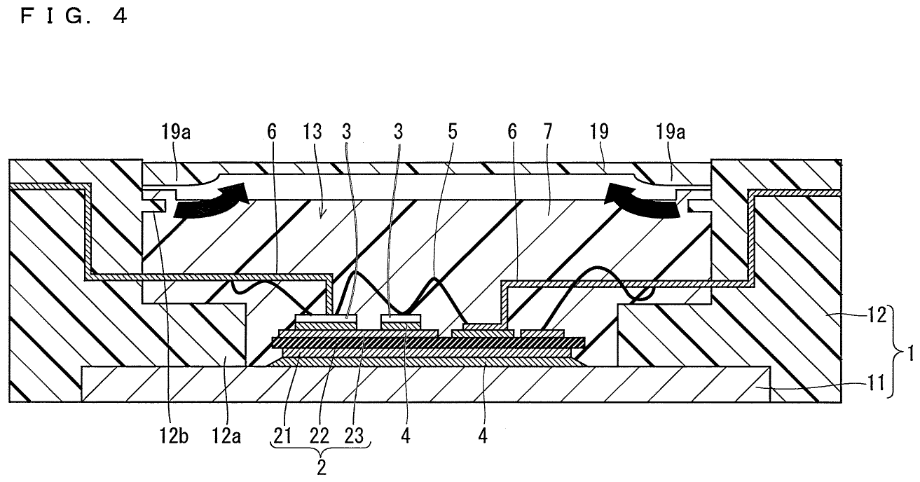

Next, a semiconductor device according to a third preferred embodiment will be described. FIG. 4 is a cross-sectional view of the semiconductor device according to the third preferred embodiment. Note that, in the third preferred embodiment, the same components as those described in the first and second preferred embodiments are denoted by the same reference numerals, and description thereof is omitted.

As illustrated in FIG. 4, in the third preferred embodiment, the semiconductor device includes a lid 19 instead of the lid 9 of the second preferred embodiment. The lid 19 is attached to the attachment portion 12b protruding from the inner peripheral surface of the case 12 toward the inner peripheral side with a gap so as to cover the opening 13. The gap between the lid 19 and the attachment portion 12b has a size through which the silicone gel 7 can pass.

The lid 19 is formed in a rectangular shape in top view, and four bulging portions 19a protruding downward are provided on the lower surfaces of the four corners of the lid 19. Specifically, the four bulging portions 19a are provided in a range corresponding to 3% or more and 5% or less of the length of each side of the lid 19 from the end of each side of the lid 19. Since the end portion of the bulging portion 19a on the central portion side of the lid 19 has a shape gently inclined toward the central portion of the lower surface of the lid 19, it is possible to guide the silicone gel 7 compressed at the time of covering to the central portion of the lower surface of the lid 19 as indicated by the arrow in FIG. 4 while securing an escape place for the silicone gel 7 compressed at the time of covering. The bulging portion 19a has the same thickness as the thickness of the lid 19. In other words, the four corners of the lid 19 where the bulging portions 19a are provided have twice the thickness of the portion other than the four corners of the lid 19.

A part of the silicone gel 7 creeps up in the case 12 due to volume expansion of the silicone gel 7 generated at the time of defoaming and heating of the silicone gel 7 filled in the case 12. The silicone gel 7 that has crept up in the case 12 is pressed at the time of covering the container 1, and a protrusion failure of the silicone gel 7 sometimes occurs. However, as described above, since the bulging portions 19a are provided on the lower surfaces of the four corners of the lid 19, it is not necessary to consider interference with other components in the container 1, and it is possible to guide the silicone gel 7 to the central portion of the lower surface of the lid 19 while securing an escape place for the silicone gel 7 compressed at the time of covering.

As described above, the semiconductor device according to the third preferred embodiment includes: the container 1 having the metal base plate 11, the case 12, and the opening 13 that opens upward; the insulating substrate 2 disposed on the metal base plate 11 in the container 1; the semiconductor element 3 mounted on the insulating substrate 2; the silicone gel 7 that is filled in the container 1 and seals the insulating substrate 2 and the semiconductor element 3; and the lid 19 that covers the opening 13 of the container 1. The lid 19 is formed in a rectangular shape in top view, and the four bulging portions 19a bulging downward are provided on the lower surfaces of the four corners of the lid 19.

Specifically, the four bulging portions 19a are provided in a range corresponding to 3% or more and 5% or less of the length of each side of the lid 19 from the end of each side of the lid 19, and have the same thickness as the thickness of the lid 19.

Therefore, since the silicone gel 7 that has crept up in the container 1 is compressed at the time of covering the container 1 and moves to the central portion of the lower surface of the lid 19 along the four bulging portions 19a, the protrusion of the silicone gel 7 can be suppressed. In addition, when this structure is adopted, it is not necessary to consider interference with other components in the container 1, and thus, it is possible to enhance the ease of manufacturing the semiconductor device.

### Fourth Preferred Embodiment

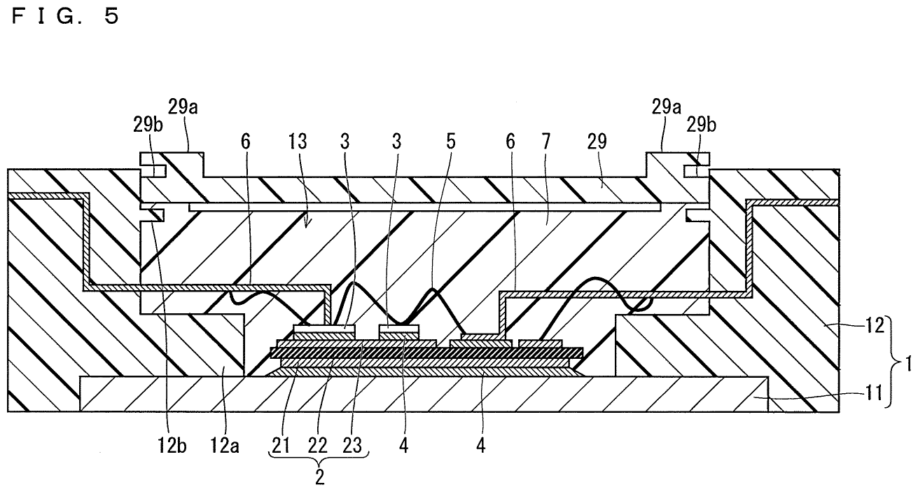

Next, a semiconductor device according to a fourth preferred embodiment will be described. FIG. 5 is a cross-sectional view of a semiconductor device according to a fourth preferred embodiment. Note that, in the fourth preferred embodiment, the same components as those described in the first to third preferred embodiments are denoted by the same reference numerals, and description thereof is omitted.

As shown in FIG. 5, in the fourth preferred embodiment, a lid 29 is provided instead of the lid 9 of the second preferred embodiment. The lid 29 is attached to the attachment portion 12b protruding from the inner peripheral surface of the case 12 toward the inner peripheral side with a gap so as to cover the opening 13. The gap between the lid 29 and the attachment portion 12b has a size through which the silicone gel 7 can pass.

The lid 29 is formed in a rectangular shape in top view, and four frame portions 29a protruding upward are provided on an upper surface (more specifically, upper surfaces of four corners of the lid 29) of a peripheral edge portion of the lid 29. Four grooves 29b recessed inward are provided in outer edge portions of the four frame portions 29a, respectively. Since the four frame portions 29a are provided on the upper surfaces of the four corners of the lid 29, the four grooves 29b are also provided in portions corresponding to the four corners of the lid 29. Each of the four grooves 29b is provided in a range corresponding to 3% or more and 5% or less of the length of each side of the lid 29 from the end of each side of the lid 29. The length and depth in the height direction of the four grooves 29b are 1% or more and 2% or less of the length of each side of the lid 29.

A part of the silicone gel 7 creeps up in the case 12 due to volume expansion of the silicone gel 7 generated at the time of defoaming and heating of the silicone gel 7 filled in the case 12. The silicone gel 7 that has crept up in the case 12 is pressed at the time of covering the container 1, and a protrusion failure of the silicone gel 7 sometimes occurs. However, as described above, since the four frame portions 29a are provided on the upper surface of the peripheral edge portion of the lid 29, and the grooves 29b are provided on the outer edge portions of the four frame portions 29a, there is no need to consider interference with other components in the container 1, and the silicone gel 7 compressed at the time of covering enters the grooves 29b via the gap between the lid 29 and the attachment portion 12b and the gap between the inner peripheral surface of the case 12 and the lid 29, whereby the silicone gel 7 can be retained in the grooves 29b.

As described above, the semiconductor device according to the fourth preferred embodiment includes: the container 1 having the metal base plate 11, the case 12, and the opening 13 that opens upward; the insulating substrate 2 disposed on the metal base plate 11 in the container 1; the semiconductor element 3 mounted on the insulating substrate 2; the silicone gel 7 that is filled in the container 1 and seals the insulating substrate 2 and the semiconductor element 3; and the lid 29 that covers the opening 13 of the container 1. The frame portions 29a protruding upward are provided on the upper surface of the peripheral edge portion of the lid 29, and the grooves 29b recessed inward are provided in outer edge portions of the frame portions 29a. Specifically, four frame portions 29a having the grooves 29b are provided, the lid 29 is formed in a rectangular shape in top view, the four grooves 29b are provided in a range corresponding to 3% or more and 5% or less of the length of each side of the lid 29 from the end of each side of the lid 29, and the length and depth in the height direction of the four grooves 29b are 1% or more and 2% or less of the length of each side of the lid 29.

Therefore, since the silicone gel 7 that has crept up in the container 1 is compressed at the time of covering the container 1 and enters the groove 29b, it is possible to suppress protrusion of the silicone gel 7 filled in the container 1. In addition, when this structure is adopted, it is not necessary to consider interference with other components in the container 1, and thus, it is possible to enhance the ease of manufacturing the semiconductor device.

Note that the preferred embodiments can be freely combined, and the preferred embodiments can be appropriately modified or omitted.

Hereinafter, various aspects of the present disclosure will be collectively described as Appendices.

### Appendix 1

A semiconductor device comprising:
a container having a bottom portion and a side wall portion;
an insulating substrate disposed on the bottom portion in the container;
a semiconductor element mounted on the insulating substrate; and
a silicone gel that is filled in the container and seals the insulating substrate and the semiconductor element,
wherein a groove having a predetermined dimension capable of generating a capillary phenomenon is provided in a portion located above an upper surface of the silicone gel in an inner peripheral surface of the side wall portion.

### Appendix 2

The semiconductor device according to Appendix 1, wherein the groove has a length in a height direction of 0.8 mm or more and 1.2 mm or less.

### Appendix 3

The semiconductor device according to Appendix 1 or 2, further comprising four grooves,
wherein the side wall portion is formed in a rectangular frame shape in a top view, and
each of the four grooves is provided at four corners of the side wall portion, and has a length in a height direction of 0.8 mm or more and 1.2 mm or less, a length in a lateral direction of 0.8 mm or more and 1.2 mm or less, and a depth of 1.6 mm or more and 2.4 mm or less.

### Appendix 4

A semiconductor device comprising:
a container having a bottom portion, a side wall portion, and an opening that opens upward;
an insulating substrate disposed on the bottom portion in the container;
a semiconductor element mounted on the insulating substrate;
a silicone gel that is filled in the container and seals the insulating substrate and the semiconductor element; and
a lid that covers the opening of the container,
wherein the lid includes an inner lid facing the silicone gel, and an outer lid located above the inner lid,
a top view contour of the inner lid is located on an inner peripheral side of a top view contour of the outer lid, and
a groove recessed toward an inner peripheral side is provided between a peripheral edge portion of the outer lid and a peripheral edge portion of the inner lid.

### Appendix 5

The semiconductor device according to Appendix 4, wherein
the top view contour of the inner lid is positioned on an inner peripheral side of
the top view contour of the outer lid by 0.8 mm or more and 1.2 mm or less, and
the groove is provided over an entire circumference between a peripheral edge portion of the outer lid and a peripheral edge portion of the inner lid, and has a depth of 0.8 mm or more and 1.2 mm or less and a length in a height direction corresponding to 24% or more and 36% or less of a thickness of the lid.

### Appendix 6

A semiconductor device comprising:
a container having a bottom portion, a side wall portion, and an opening that opens upward;
an insulating substrate disposed on the bottom portion in the container;
a semiconductor element mounted on the insulating substrate;
a silicone gel that is filled in the container and seals the insulating substrate and the semiconductor element; and
a lid that covers the opening of the container,
wherein the lid is formed in a rectangular shape as viewed in a top view, and
four bulging portions bulging downward are provided on lower surfaces of four corners of the lid, respectively.

### Appendix 7

The semiconductor device according to Appendix 6, wherein the four bulging portions are provided in a range corresponding to 3% or more and 5% or less of a length of each side of the lid from an end of each side of the lid, and have a thickness same as a thickness of the lid.

### Appendix 8

A semiconductor device comprising:
a container having a bottom portion, a side wall portion, and an opening that opens upward;
an insulating substrate disposed on the bottom portion in the container;
a semiconductor element mounted on the insulating substrate;
a silicone gel that is filled in the container and seals the insulating substrate and the semiconductor element; and
a lid that covers the opening of the container,
wherein a frame portion protruding upward is provided on an upper surface of a peripheral edge portion of the lid, and
a groove recessed inward is provided in an outer edge portion of the frame portion.

### Appendix 9

The semiconductor device according to Appendix 8, wherein
four frame portions each having the groove are provided,
the lid is formed in a rectangular shape as viewed in a top view,
each of the four grooves is provided in a range corresponding to 3% or more and 5% or less of a length of each side of the lid from an end of each side of the lid, and
a length and a depth in a height direction of the four grooves are 1% or more and 2% or less of the length of each side of the lid.

While the disclosure has been shown and described in detail, the foregoing description is in all aspects illustrative and not restrictive. It is therefore understood that numerous modifications and variations can be devised.

What is claimed is:

1. A semiconductor device comprising:
a container having a bottom portion and a side wall portion;
an insulating substrate disposed on the bottom portion in the container;
a semiconductor element mounted on the insulating substrate; and
a silicone gel that is filled in the container and seals the insulating substrate and the semiconductor element,
wherein a groove having a predetermined dimension capable of generating a capillary phenomenon is provided in a portion located above an upper surface of the silicone gel in an inner peripheral surface of the side wall portion.

2. The semiconductor device according to claim 1, wherein the groove has a length in a height direction of 0.8 mm or more and 1.2 mm or less.

3. The semiconductor device according to claim 1, further comprising four grooves,
wherein the side wall portion is formed in a rectangular frame shape in a top view, and
each of the four grooves is provided at four corners of the side wall portion, and has a length in a height direction of 0.8 mm or more and 1.2 mm or less, a length in a lateral direction of 0.8 mm or more and 1.2 mm or less, and a depth of 1.6 mm or more and 2.4 mm or less.

4. A semiconductor device comprising:
a container having a bottom portion, a side wall portion, and an opening that opens upward;
an insulating substrate disposed on the bottom portion in the container;
a semiconductor element mounted on the insulating substrate;
a silicone gel that is filled in the container and seals the insulating substrate and the semiconductor element; and
a lid that covers the opening of the container,
wherein the lid includes an inner lid facing the silicone gel, and an outer lid located above the inner lid,
a top view contour of the inner lid is located on an inner peripheral side of a top view contour of the outer lid, and
a groove recessed toward an inner peripheral side is provided between a peripheral edge portion of the outer lid and a peripheral edge portion of the inner lid.

5. The semiconductor device according to claim 4, wherein
the top view contour of the inner lid is positioned on an inner peripheral side of the top view contour of the outer lid by 0.8 mm or more and 1.2 mm or less, and
the groove is provided over an entire circumference between a peripheral edge portion of the outer lid and a peripheral edge portion of the inner lid, and has a depth of 0.8 mm or more and 1.2 mm or less and a length in a height direction corresponding to 24% or more and 36% or less of a thickness of the lid.

6. A semiconductor device comprising:
a container having a bottom portion, a side wall portion, and an opening that opens upward;
an insulating substrate disposed on the bottom portion in the container;
a semiconductor element mounted on the insulating substrate;
a silicone gel that is filled in the container and seals the insulating substrate and the semiconductor element; and
a lid that covers the opening of the container,
wherein the lid is formed in a rectangular shape as viewed in a top view, and
four bulging portions bulging downward are provided on lower surfaces of four corners of the lid, respectively.

7. The semiconductor device according to claim 6, wherein the four bulging portions are provided in a range corresponding to 3% or more and 5% or less of a length of each side of the lid from an end of each side of the lid, and have a thickness same as a thickness of the lid.

8. A semiconductor device comprising:
a container having a bottom portion, a side wall portion, and an opening that opens upward;
an insulating substrate disposed on the bottom portion in the container;
a semiconductor element mounted on the insulating substrate;
a silicone gel that is filled in the container and seals the insulating substrate and the semiconductor element; and
a lid that covers the opening of the container,
wherein a frame portion protruding upward is provided on an upper surface of a peripheral edge portion of the lid, and
a groove recessed inward is provided in an outer edge portion of the frame portion.

9. The semiconductor device according to claim 8, wherein
four frame portions each having the groove are provided,
the lid is formed in a rectangular shape as viewed in a top view,
each of the four grooves is provided in a range corresponding to 3% or more and 5% or less of a length of each side of the lid from an end of each side of the lid, and
a length and a depth in a height direction of the four grooves are 1% or more and 2% or less of the length of each side of the lid.
